(19) United States
(12) Patent Application Publication
(10) Pub. No.: US 2018/0122640 A1
(43) Pub. Date: May 3, 2018

(54) SCREEN-PRINTABLE BORON DOPING PASTE WITH SIMULTANEOUS INHIBITION OF PHOSPHORUS DIFFUSION IN CO-DIFFUSION PROCESSES

(71) Applicant: MERCK PATENT GMBH, Darmstadt (DE)

(72) Inventors: Oliver DOLL, Dietzenbach (DE); Ingo KOEHLER, Darmstadt (DE); Sebastian BARTH, Darmstadt (DE)

(73) Assignee: MERCK PATENT GMBH, Darmstadt (DE)

(21) Appl. No.: 15/566,954

(22) PCT Filed: Mar. 24, 2016
(86) PCT No.: PCT/EP2016/000518

§ 371 Date: Oct. 16, 2017

(30) Foreign Application Priority Data
Apr. 15, 2015 (EP) 15001073.4

(51) Int. Cl. H01L 21/225; H01L 31/18; C09D 11/52; C09D 11/03; C09D 11/32; C30B 31/04

(52) U.S. Cl. CPC H01L 21/2254; H01L 31/1804; C30B 31/04; C09D 11/03; C09D 11/32; C09D 11/52

(57) ABSTRACT

The present invention relates to a novel printable boron doping paste in the form of a hybrid gel based on precursors of inorganic oxides, preferably of silicon dioxide, aluminium oxide and boron oxide, in the presence of organic polymer particles, where the pastes according to the invention can be used in a simplified process for the production of solar cells, where the hybrid gel according to the invention functions both as doping medium and as diffusion barrier.

The present invention relates to a novel printable boron doping paste in the form of a hybrid gel based on precursors of inorganic oxides, preferably of silicon dioxide, aluminium oxide and boron oxide, in the presence of organic polymer particles, where the pastes according to the invention can be used in a simplified process for the production of solar cells, where the hybrid gel according to the invention functions both as doping medium and as diffusion barrier.

### PRIOR ART

The production of simple solar cells or the solar cells which are currently represented with the greatest market share in the market comprises the essential production steps outlined below:

1. Saw-Damage Etching and Texture

A silicon wafer (monocrystalline, multicrystalline or quasi-monocrystalline, base doping p or n type) is freed from adherent saw damage by means of etching methods and “simultaneously” textured, generally in the same etching bath. Texturing is in this case taken to mean the creation of a preferentially aligned surface (nature) as a consequence of the etching step or simply the intentional, but not particularly aligned roughening of the wafer surface. As a consequence of the texturing, the surface of the wafer now acts as a diffuse reflector and thus reduces the directed reflection, which is dependent on the wavelength and on the angle of incidence, ultimately resulting in an increase in the absorbed proportion of the light incident on the surface and thus an increase in the conversion efficiency of the solar cell.

The above-mentioned etching solutions for the treatment of the silicon wafers typically consist, in the case of monocrystalline wafers, of dilute potassium hydroxide solution to which isopropyl alcohol has been added as solvent. Other alcohols having a higher vapour pressure or a higher boiling point than isopropyl alcohol may also be added instead if this enables the desired etching result to be achieved. The desired etching result obtained is typically a morphology which is characterised by pyramids having a square base which are randomly arranged, or rather etched out of the original surface. The density, the height and thus the base area of the pyramids can be partly influenced by a suitable choice of the above-mentioned components of the etching solution, the etching temperature and the residence time of the wafers in the etching tank. The texturing of the monocrystalline wafers is typically carried out in the temperature range from 70-<90° C., where up to 10 μm of material per wafer side can be removed by etching.

In the case of multicrystalline silicon wafers, the etching solution can consist of potassium hydroxide solution having a moderate concentration (10-15%). However, this etching technique is hardly still used in industrial practice. More frequently, an etching solution consisting of nitric acid, hydrofluoric acid and water is used. This etching solution can be modified by various additives, such as, for example, sulfuric acid, phosphoric acid, acetic acid, N-methylpyrrolidone, and also surfactants, enabling, inter alia, wetting properties of the etching solution and also its etching rate to be specifically influenced. These acidic etch mixtures produce a morphology of nested etching trenches on the surface. The etching is typically carried out at temperatures in the range between 4° C. and <10° C., and the amount of material removed by etching here is generally 4 μm to 6 μm.

Immediately after the texturing, the silicon wafers are cleaned intensively with water and treated with dilute hydrofluoric acid in order to remove the chemical oxide layer formed as a consequence of the preceding treatment steps and contaminants absorbed and adsorbed therein and also thereon, in preparation for the subsequent high-temperature treatment.

2. Diffusion and Doping

The wafers etched and cleaned in the preceding step (in this case p-type base doping) are treated with vapour consisting of phosphorus oxide at elevated temperatures, typically between 750° C. and <1000° C. During this operation, the wafers are exposed to a controlled atmosphere consisting of dried nitrogen, dried oxygen and phosphoryl chloride in a quartz tube in a tubular furnace. To this end, the wafers are introduced into the quartz tube at temperatures between 600 and 700° C. The gas mixture is transported through the quartz tube. During the transport of the gas mixture through the strongly warmed tube, the phosphoryl chloride decomposes to give a vapour consisting of phosphorus oxide (for example P₂O₅) and chlorine gas. The phosphorus oxide vapour precipitates, inter alia, on the wafer surfaces (coating). At the same time, the silicon surface is oxidised at these temperatures with formation of a thin oxide layer. The precipitated phosphorus oxide is embedded in this layer, causing mixed oxide of silicon dioxide and phosphorus oxide to form on the wafer surface. This mixed oxide is known as phosphosilicate glass (PSG). This PSG has different softening points and different diffusion constants with respect to the phosphorus oxide depending on the concentration of the phosphorus oxide present. The mixed oxide serves as diffusion source for the silicon wafer, where the phosphorus oxide diffuses in the course of the diffusion in the direction of the interface between PSG and silicon wafer, where it is reduced to phosphorus by reaction with the silicon at the wafer surface (silicothermally). The phosphorus formed in this way has a solubility in silicon which is orders of magnitude higher than in the glass matrix from which it has been formed and thus preferentially dissolves in the silicon owing to the very high segregation coefficient. After dissolution, the phosphorus diffuses in the silicon along the concentration gradient into the volume of the silicon. In this diffusion process, concentration gradients in the order of 10⁵ form between typical surface concentrations of 10²¹ atoms/cm² and the base doping in the region of 10¹⁶ atoms/cm². The typical diffusion depth is 250 to 500 nm and is dependent on the diffusion temperature selected (for example 880° C.), and the total exposure duration (heating & coating phase & drive-in phase & cooling) of the wafers in the strongly warmed atmosphere. During the coating phase, a PSG layer forms which typically has a layer thickness of 40 to 60 nm. The coating of the wafers with the PSG, during which diffusion into the volume of the silicon also already takes place, is followed by the drive-in phase. This can be decoupled from the coating phase, but is in practice generally coupled directly to the coating in terms of time and is therefore usually also carried out at the same temperature. The composition of the gas mixture here is adapted in such a way that the further supply of phosphoryl chloride is suppressed. During drive-in, the surface of the silicon is oxidised further by the oxygen present in the gas mixture, causing a phosphorus oxide-depleted silicon dioxide layer which likewise comprises phosphorus oxide to be generated between the actual doping source, the highly phosphorus oxide-enriched PSG, and the silicon wafer. The growth of this layer is very much faster in relation to the mass flow of the dopant from the source (PSG), since the oxide growth is accelerated by the high surface doping of the wafer itself (acceleration by one to two orders of magnitude). This enables depletion or separation of the doping source to be achieved in a certain manner, permeation of which with phosphorus oxide diffusing on is influenced by the material flow, which is dependent on the temperature and thus the diffusion coefficient. In this way, the doping of the silicon can be controlled in certain limits. A typical diffusion duration consisting of coating phase and drive-in phase is, for example, 25 minutes. After this treatment, the tubular furnace is automatically cooled, and the wafers can be removed from the process tube at temperatures between 600° C. and 700° C.

In the case of boron doping of the wafers in the form of n-type base doping, a different method is used, which will not be explained separately here. The doping in these cases is carried out, for example, with boron trichloride or boron tribromide. Depending on the choice of the composition of the gas atmosphere employed for the doping, the formation of a so-called boron skin on the wafers may be observed. This boron skin is dependent on various influencing factors: crucially the doping atmosphere, the temperature, the doping duration, the source concentration and the coupled (or linear-combined) parameters mentioned above.

In such diffusion processes, it goes without saying that the wafers used cannot contain any regions of preferred diffusion and doping (apart from those which are formed by inhomogeneous gas flows and resultant gas pockets of inhomogeneous composition) if the substrates have not previously been subjected to a corresponding pretreatment (for example structuring thereof with diffusion-inhibiting and/or -suppressing layers and materials).

For completeness, it should also be pointed out here that there are also further diffusion and doping technologies which have become established to different extents in the production of crystalline solar cells based on silicon. Thus, mention may be made of:
ion implantation,
doping promoted via the gas-phase deposition of mixed oxides, such as, for example, those of PSG and BSG (borosilicate glass), by means of APCVD, PECVD, MOCVD and LPCVD processes,
(co)sputtering of mixed oxides and/or ceramic materials and hard materials (for example boron nitride), gas-phase deposition of the latter two, purely thermal gas-phase deposition starting from solid dopant sources (for example boron oxide and boron nitride), and
liquid-phase deposition of liquids (inks) and pastes having a doping action.

The latter are frequently used in so-called inline doping, in which the corresponding pastes and inks are applied by means of suitable methods to the wafer side to be doped. After or also even during the application, the solvents present in the compositions employed for the doping are removed by temperature and/or vacuum treatment. This leaves the actual dopant behind on the wafer surface. Liquid doping sources which can be employed are, for example, dilute solutions of phosphoric or boric acid, and also sol-gel-based systems or also solutions of polymeric borazil compounds. Corresponding doping pastes are characterised virtually exclusively by the use of additional thickening polymers, and comprise dopants in suitable form. The evaporation of the solvents from the above-mentioned doping media is usually followed by treatment at high temperature, during which undesired and interfering additives, but ones which are necessary for the formulation, are either “burnt” and/or pyrolysed. The removal of solvents and the burning-out may, but do not have to, take place simultaneously. The coated substrates subsequently usually pass through a through-flow furnace at temperatures between 800° C. and 1000° C., where the temperatures may be slightly increased compared with gas-phase diffusion in the tubular furnace in order to shorten the passage time. The gas atmosphere prevailing in the through-flow furnace may differ in accordance with the requirements of the doping and may consist of dry nitrogen, dry air, a mixture of dry oxygen and dry nitrogen and/or, depending on the design of the furnace to be passed through, zones of one or other of the above-mentioned gas atmospheres. Further gas mixtures are conceivable, but currently do not have major importance industrially. A characteristic of inline diffusion is that the coating and drive-in of the dopant can in principle take place decoupled from one another.

3. Removal of the Dopant Source and Optional Edge Insulation

The wafers present after the doping are coated on both sides with more or less glass on both sides of the surface. “More or less” in this case refers to modifications which can be applied during the doping process: double-sided diffusion vs. quasi-single-sided diffusion promoted by back-to-back arrangement of two wafers in one location of the process boats used. The latter variant enables predominantly single-sided doping, but does not completely suppress diffusion on the back. In both cases, the current state of the art is removal of the glasses present after the doping from the surfaces by means of etching in dilute hydrofluoric acid. To this end, the wafers are on the one hand reloaded in batches into wet-process boats and with the aid of the latter dipped into a solution of dilute hydrofluoric acid, typically 2% to 5%, and left therein until either the surface has been completely freed from the glasses, or the process cycle duration, which represents a sum parameter of the requisite etching duration and the process automation by machine, has expired. The complete removal of the glasses can be established, for example, from the complete dewetting of the silicon wafer surface by the dilute aqueous hydrofluoric acid solution. The complete removal of a PSG is achieved within 210 seconds at room temperature under these process conditions, for example using 2% hydrofluoric acid solution. The etching of corresponding BSGs is slower and requires longer process times and possibly also higher concentrations of the hydrofluoric acid used. After the etching, the wafers are rinsed with water.

On the other hand, the etching of the glasses on the wafer surfaces can also be carried out in a horizontally operating process, in which the wafers are introduced in a constant flow into an etcher in which the wafers pass horizontally through the corresponding process tanks (inline machine). In this case, the wafers are conveyed on rollers either through the process tanks and the etching solutions present therein, or the etch media are transported onto the wafer surfaces by means of roller application. The typical residence time of the wafers during etching of the PSG is about 90 seconds, and the hydrofluoric acid used is somewhat more highly concentrated than in the case of the batch process in order to compensate for the shorter residence time as a consequence of an increased etching rate. The concentration of the hydrofluoric acid is typically 5%. The tank temperature may optionally additionally be slightly increased compared with room temperature (>25° C.<50° C.).

In the process outlined last, it has become established to carry out the so-called edge insulation sequentially at the same time, giving rise to a slightly modified process flow: edge insulation→glass etching. Edge insulation is a technical necessity in the process which arises from the system-inherent characteristic of double-sided diffusion, also in the case of intentional single-sided back-to-back diffusion. A large-area parasitic p-n junction is present on the (later) back of the solar cell, which is, for process-engineering reasons, removed partially, but not completely, during the later processing. As a consequence of this, the front and back of the solar cell will have been short-circuited via a parasitic and residue p-n junction (tunnel contact), which reduces the conversion efficiency of the later solar cell. For removal of this junction, the wafers are passed on one side over an etching solution consisting of nitric acid and hydrofluoric acid. The etching solution may comprise, for example, sulfuric acid or phosphoric acid as secondary constituents. Alternatively, the etching solution is transported (conveyed) via rollers onto the back of the wafer. About 1 μm of silicon (including the glass layer present on the surface to be treated) is typically removed by etching in this process at temperatures between 4° C. and 8° C. In this process, the glass layer still present on the opposite side of the wafer serves as a mask, which provides a certain protection against overetching onto this side. This glass layer is subsequently removed with the aid of the glass etching already described.

In addition, the edge insulation can also be carried out with the aid of plasma etching processes. This plasma etching is then generally carried out before the glass etching. To this end, a plurality of wafers are stacked one on top of the other, and the outside edges are exposed to the plasma. The plasma is fed with fluorinated gases, for example tetrafluoromethane. The reactive species occurring on plasma decomposition of these gases etch the edges of the wafer. In general, the plasma etching is then followed by the glass etching.

4. Coating of the Front Surface with an Antireflection Layer

After the etching of the glass and the optional edge insulation, the front surface of the later solar cells is coated with an antireflection coating, which usually consists of amorphous and hydrogen-rich silicon nitride. Alternative antireflection coatings are conceivable. Possible coatings may consist of titanium dioxide, magnesium fluoride, tin dioxide and/or corresponding stacked layers of silicon dioxide and silicon nitride. However, antireflection coatings having a different composition are also technically possible. The coating of the wafer surface with the above-mentioned silicon nitride essentially fulfills two functions: on the one hand the layer generates an electric field owing to the numerous incorporated positive charges, which can keep charge carriers in the silicon away from the surface and can considerably reduce the recombination rate of these charge carriers at the silicon surface (field-effect passivation), on the other hand this layer generates a reflection-reducing property, depending on its optical parameters, such as, for example, refractive index and layer thickness, which contributes to it being possible for more light to be coupled into the later solar cell. The two effects can increase the conversion efficiency of the solar cell. Typical properties of the layers currently used are: a layer thickness of ˜80 nm on use of exclusively the above-mentioned silicon nitride, which has a refractive index of about 2.05. The antireflection reduction is most clearly apparent in the light wavelength region of 600 nm. The directed and undirected reflection here exhibits a value of about 1% to 3% of the originally incident light (perpendicular incidence to the surface perpendicular of the silicon wafer).

The above-mentioned silicon nitride layers are currently generally deposited on the surface by means of the direct PECVD process. To this end, a plasma into which silane and ammonia are introduced is ignited in an argon gas atmosphere. The silane and the ammonia are reacted in the plasma via ionic and free-radical reactions to give silicon nitride and at the same time deposited on the wafer surface. The properties of the layers can be adjusted and controlled, for example, via the individual gas flows of the reactants. The deposition of the above-mentioned silicon nitride layers can also be carried out with hydrogen as carrier gas and/or the reactants alone. Typical deposition temperatures are in the range between 300° C. and 400° C. Alternative deposition methods can be, for example, LPCVD and/or sputtering.

5. Production of the Front Surface Electrode Grid

After deposition of the antireflection layer, the front surface electrode is defined on the wafer surface coated with silicon nitride. In industrial practice, it has become established to produce the electrode with the aid of the screen-printing method using metallic sinter pastes. However, this is only one of many different possibilities for the production of the desired metal contacts.

In screen-printing metallisation, a paste which is highly enriched with silver particles (silver content ≤80%) is generally used. The sum of the remaining constituents arises from the rheological assistants necessary for formulation of the paste, such as, for example, solvents, binders and thickeners. Furthermore, the silver paste comprises a special glass-frit mixture, usually oxides and mixed oxides based on silicon dioxide, borosilicate glass and also lead oxide and/or bismuth oxide. The glass frit essentially fulfills two functions: it serves on the one hand as adhesion promoter between the wafer surface and the mass of the silver particles to be sintered, on the other hand it is responsible for penetration of the silicon nitride top layer in order to facilitate direct ohmic contact with the underlying silicon. The penetration of the silicon nitride takes place via an etching process with subsequent diffusion of silver dissolved in the glass-frit matrix into the silicon surface, whereby the ohmic contact formation is achieved. In practice, the silver paste is deposited on the wafer surface by means of screen printing and subsequently dried at temperatures of about 200° C. to 300° C. for a few minutes. For completeness, it should be mentioned that double-printing processes are also used industrially, which enable a second electrode grid to be printed with accurate registration onto an electrode grid generated during the first printing step. The thickness of the silver metallisation is thus increased, which can have a positive influence on the conductivity in the electrode grid. During this drying, the solvents present in the paste are expelled from the paste. The printed wafer subsequently passes through a through-flow furnace. An furnace of this type generally has a plurality of heating zones which can be activated and temperature-controlled independently of one another. During passivation of the through-flow furnace, the wafers are heated to temperatures up to about 950° C. However, the individual wafer is generally only subjected to this peak temperature for a few seconds. During the remainder of the through-flow phase, the wafer has temperatures of 600° C. to 800° C. At these temperatures, organic accompanying substances present in the silver paste, such as, for example, binders, are burnt out, and the etching of the silicon nitride layer is initiated. During the short time interval of prevailing peak temperatures, the contact formation with the silicon takes place. The wafers are subsequently allowed to cool.

The contact formation process outlined briefly in this way is usually carried out simultaneously with the two remaining contact formations (cf. 6 and 7), which is why the term co-firing process is also used in this case.

The front surface electrode grid consists per se of thin fingers (typical number ≥68) which have a width of typically 80 μm to 140 μm, and also busbars having widths in the range from 1.2 mm to 2.2 mm (depending on their number, typically two to three). The typical height of the printed silver elements is generally between 10 μm and 25 μm. The aspect ratio is rarely greater than 0.3.

6. Production of the Back Surface Busbars

The back surface busbars are generally likewise applied and defined by means of screen-printing processes. To this end, a similar silver paste to that used for the front surface metallisation is used. This paste has a similar composition, but comprises an alloy of silver and aluminium in which the proportion of aluminium typically makes up 2%. In addition, this paste comprises a lower glass-frit content. The busbars, generally two units, are printed onto the back of the wafer by means of screen printing with a typical width of 4 mm and are compacted and sintered as already described under point 5.

7. Production of the Back Surface Electrode

The back surface electrode is defined after the printing of the busbars. The electrode material consists of aluminium, which is why an aluminium-containing paste is printed onto the remaining free area of the wafer back by means of screen printing with an edge separation <1 mm for definition of the electrode. The paste is composed of ≤80% of aluminium. The remaining components are those which have already been mentioned under point 5 (such as, for example, solvents, binders, etc.). The aluminium paste is bonded to the wafer during the co-firing by the aluminium particles beginning to melt during the warming and silicon from the wafer dissolving in the molten aluminium. The melt mixture functions as dopant source and releases aluminium to the silicon (solubility limit: 0.016 atom percent), where the silicon is p⁺-doped as a consequence of this drive-in. During cooling of the wafer, a eutectic mixture of aluminium and silicon, which solidifies at 577° C. and has a composition having a mole fraction of 0.12 of Si, deposits, inter alia, on the wafer surface.

As a consequence of the drive-in of the aluminium into the silicon, a highly doped p-type layer, which functions as a type of mirror (“electric mirror”) on parts of the free charge carriers in the silicon, forms on the back of the wafer. These charge carriers cannot overcome this potential wall and are thus kept away from the back wafer surface very efficiently, which is thus evident from an overall reduced recombination rate of charge carriers at this surface. This potential wall is generally referred to as “back surface field”.

The sequence of the process steps described under points 5, 6 and 7 may, but does not have to, correspond to the sequence outlined here. It is evident to the person skilled in the art that the sequence of the outlined process steps can in principle be carried out in any conceivable combination.

8. Optional Edge Insulation

If the edge insulation of the wafer has not already been carried out as described under point 3, this is typically carried out with the aid of laser-beam methods after the co-firing. To this end, a laser beam is directed at the front of the solar cell, and the front surface p-n junction is parted with the aid of the energy coupled in by this beam. Cut trenches having a depth of up to 15 μm are generated here as a consequence of the action of the laser. Silicon is removed from the treated site via an ablation mechanism or ejected from the laser trench. This laser trench typically has a width of 30 μm to 60 μm and is about 200 μm away from the edge of the solar cell.

After production, the solar cells are characterised and classified in individual performance categories in accordance with their individual performances.

The person skilled in the art is familiar with solar-cell architectures with both n-type and also p-type base material. These solar cell types include, inter alia,
PERC solar cells,
PERL solar cells,
PERT solar cells,
MWT-PERT and MWT-PERL solar cells derived therefrom,
bifacial solar cells,
back surface contact cells,
back surface contact cells with interdigital contacts (IBC cells).

The choice of alternative doping technologies, as an alternative to the gas-phase doping already described in the introduction, is generally also incapable of solving the problem of the creation of locally differently doped regions on the silicon substrate. Alternative technologies which may be mentioned here are the deposition of doped glasses, or of amorphous mixed oxides, by means of PECVD and APCVD processes. Thermally induced doping of the silicon located beneath these glasses can easily be achieved from these glasses. In order to create locally differently doped regions, however, these glasses must be etched by means of mask processes in order to produce the corresponding structures from them. Alternatively, structured diffusion barriers against the deposition of the glasses can be deposited on the silicon wafers in order thus to define the regions to be doped. However, it is disadvantageous in this process that in each case only one polarity (n or p) can be achieved in the doping of the substrates.

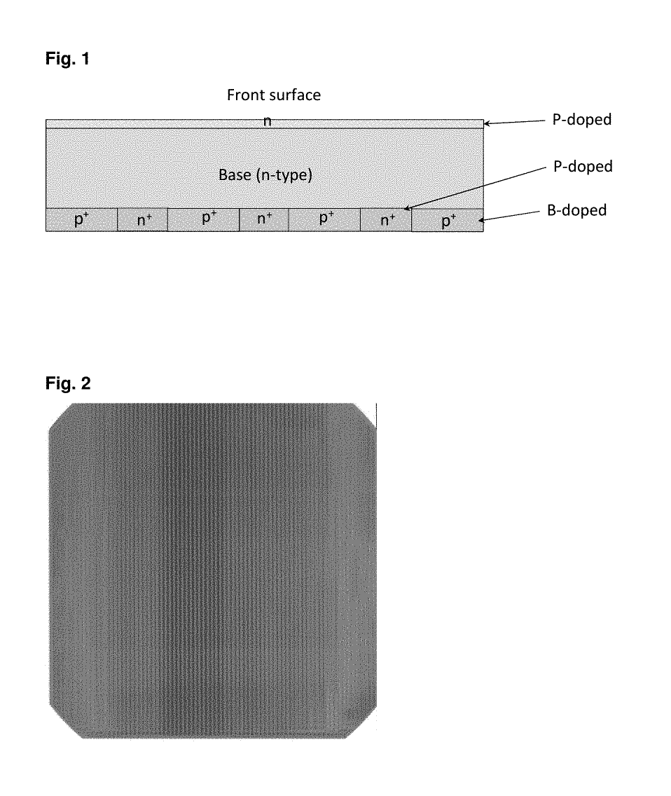

FIG. 1: shows a simplified cross-section through an IBC solar cell (not to scale, without surface texture, without antireflection and passivation layers, without back-surface metallisation). The alternating pn junctions can have different arrangements, such as, for example, directly adjacent to one another, or with gaps with intrinsic regions.

Let us concentrate below in a simplified manner on a possible excerpt of the production process of a so-called IBC solar cell (FIG. 1). This excerpt and thus outlined part-process makes no claim to completeness or to exclusivity in this consideration. Deviations and modifications of the process chain described can easily be imagined and also achieved. The starting point is a CZ wafer, which has, for example, a surface which is alkaline-polished or saw damage-etched on one side. This wafer is coated over the entire surface on one side, which is not polished and is thus the later front surface, by means of a CVD oxide of suitable thickness, such as, for example, 200 nm or more. After the coating with the CVD oxide on one side, the wafer is subjected to B diffusion in a conventional tubular furnace, by means of, for example, boron tribromide as precursor. After the boron diffusion, the wafer must be locally structured on the now-diffused back surface in order to define and ultimately to create the regions for the later contacts to the base and for the production of the local back surface field diffused with phosphorus in this case. This structuring can be achieved, for example, with the aid of a laser, which locally ablates the doped glass present on the back surface. The use of laser radiation in the production of highly efficient solar cells is controversial owing to the damage to the bulk of the silicon wafer. For simplicity, however, let us assume that it were possible and there were or are no further fundamental problems. The indisputably damaged silicon present at least at the surface must then, after the laser treatment, be removed with the aid of an alkaline damage etch. In practical terms, the boron emitter present at this point is simultaneously dissolved and removed (if it were in this case likewise assumed that, as usually known, highly boron-doped silicon is not an etch stop for KOH-based etch solutions)—if it can justifiably be assumed that the remaining borosilicate glass (BSG) at the closed points represents adequate protection of the silicon against the KOH solution (etching rate of SiO₂ in 30% KOH at 80° C. is about 3 nm/min, this could be somewhat higher in KOH if a “disordered oxide” is assumed in the case of BSG). A plateau or a type of trench is etched into the silicon here. Alternatively, the base contacts to the later local back surface field could be created by applying an etch mask to the back surface, for example by means of screen printing, and subsequently treating the open points with the aid of two consecutive or even only one etching step: removal of the glass from one surface by etching in hydrofluoric acid and subsequent etching in KOH solution, or etching of both materials in one step. Either the etch mask and the doped glass or only the doped glass would subsequently be removed, in each case from one side on the back surface. A CVD oxide layer would subsequently be deposited on the back surface of the wafer and locally opened and structured, to be precise at the points at which the boron emitter had previously been removed. The wafers would subsequently be subjected to phosphorus diffusion. Depending on how the process parameters of this diffusion looked in detail, it would also only be necessary to carry out the structurings described above once, to be precise, for example, in a case where the performance of phosphorus diffusion would no longer influence the boron doping profile already obtained in the simultaneous presence of BSG glass, or would indeed influence it in a controllable manner. The wafers would subsequently be freed on one side from the protecting oxide on their front surface and subjected to weak phosphorus diffusion. For simplicity, it has been assumed at this point that the BSG glass present on the back surface can remain on the wafer surface and would thus not cause any further interferences or influences. After the weak diffusion on the front surface, the wafers are etched with hydrofluoric acid and all oxides and glasses are removed. In total, the process outlined above is characterised by the following steps and their total number (described in simplified terms for structuring by means of a laser process; in the case of the use of etch resists, printing and stripping of the resist would also have to be added):

1. Oxide mask over the entire front surface

2. Boron diffusion

3. Structuring and etching of the back surface

4. Oxide mask over the entire back surface

5. Structuring of the back surface

6. Phosphorus diffusion

7. Removal of oxide mask on the front surface

8. Phosphorus diffusion

9. Removal of all glasses

In total, nine process steps are needed in order to achieve structured doping of the wafer. By contrast, depending on the counting method, eight process steps are needed for the production of an entire standard aluminium BSF solar cell. In the production of IBC cells, other possibilities may be able to be used, the effort for achieving structured dopings is very high in each case and is expensive in each of these cases, in some cases just as expensive as the production of a single standard aluminium BSF solar cell. The further spread of this cell technology will in each case be dependent on the reduction of process costs, which will therefore significantly profit from the establishment of simplifying process alternatives which nevertheless allow high cell efficiencies.

Object

The doping technologies usually used in the industrial production of solar cells, especially by gas phase-promoted diffusion with reactive precursors, such as phosphoryl chloride and/or boron tribromide, do not enable local dopings and/or locally different dopings to be generated on silicon wafers in a targeted manner. The creation of such structures using known doping technologies is only possible through complex and expensive structuring of the substrates. During the structuring, various masking processes must be matched to one another, which makes industrial mass production of such substrates very complex. For this reason, concepts for the production of solar cells which require such structuring have hitherto not been able to establish themselves. The object of the present invention is therefore to provide an inexpensive process which is simple to carry out, and a medium which can be employed in this process, whereby these problems and the masking steps which are normally necessary are obsolete and are thus eliminated. In addition, the doping source which can be applied locally is distinguished by the fact that it can preferably be applied to the wafer surfaces by means of known printing technologies which are established in solar cell manufacturing technology. In addition, the special feature of the process according to the invention arises from the fact that the printable doping media used have a diffusion-inhibiting action against the gas phase dopant phosphoryl chloride which is conventionally used in industry, and also similar dopants (which, correctly expressed, can be dopants which are converted into phosphorus pentoxide as a consequence of their combustion in the gas phase) and thus allow in the simplest manner simultaneous, but also any desired sequential diffusions and dopings with two dopants for either simultaneous or sequential doping of opposite polarities in silicon.

### BRIEF DESCRIPTION OF THE INVENTION

The present invention relates to printable boron doping pastes and/or gels based on precursors, such as of silicon dioxide, aluminium oxide and boron oxide, which are printed onto silicon surfaces for the purposes of local and/or full-area diffusion and doping on one side by means of suitable printing processes in the production of solar cells, preferably of highly efficient solar cells doped in a structured manner, dried and subsequently brought to specific doping of the substrate itself by means of a suitable high-temperature process for release of the boron oxide precursor present in the dried paste to the substrate located beneath the boron paste.

The printable boron doping pastes are based on precursors of the following oxide materials:
a) silicon dioxide: symmetrically and asymmetrically mono- to tetrasubstituted carboxy-, alkoxy- and alkoxyalkylsilanes, explicitly containing alkylalkoxysilanes, in which the central silicon atom can have a degree of substitution of [lacuna] by at least one hydrogen atom bonded directly to the silicon atom, such as, for example, triethoxysilane, and where furthermore a degree of substitution relates to the number of possible carboxyl and/or alkoxy groups present, which, both in the case of alkyl and/or alkoxy and/or carboxyl groups, contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of the above-mentioned precursors; individual compounds which satisfy the above-mentioned demands are: tetraethyl orthosilicate and the like, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane
b) aluminium oxide: symmetrically and asymmetrically substituted aluminium alcoholates (alkoxides), such as aluminium triethanolate, aluminium triisopropylate, aluminium tri-sec-butylate, aluminium tributylate, aluminium triamylate and aluminium triisopentanolate, aluminium tris(β-diketones), such as aluminium acetylacetonate or aluminium tris(1,3-cyclohexanedionate), aluminium tris(β-ketoesters), aluminium monoacetylacetonate monoalcoholate, aluminium tris(hydroxyquinolate), aluminium soaps, such as mono- and dibasic aluminium stearate and aluminium tristearate, aluminium carboxylates, such as basic aluminium acetate, aluminium triacetate, basic aluminium formate, aluminium triformate and aluminium trioctanoate, aluminium hydroxide, aluminium metahydroxide and aluminium trichloride and the like, and mixtures thereof.
c) boron oxide: diboron oxide, simple alkyl borates, such as triethyl borate, triisopropyl borate, boric acid esters of functionalised 1,2-glycols, such as, for example, ethylene glycol, functionalised 1,2,3-triols, such as, for example, glycerol, functionalised 1,3-glycols, such as, for example, 1,3-propanediol, boric acid esters with boric acid esters which contain the above-mentioned structural motifs as structural sub-units, such as, for example, 2,3-dihydroxysuccinic acid and enantiomers thereof, boric acid esters of ethanolamine, diethanolamine, triethanolamine, propanolamine, dipropanolamine and tripropanolamine, mixed anhydrides of boric acid and carboxylic acids, such as, for example, tetraacetoxy diborate, boric acid, metaboric acid, and mixtures of the above-mentioned precursors,

which are brought to partial or complete intra- and/or interspecies condensation under water-containing or anhydrous conditions with the aid of the sol-gel technique, either simultaneously or sequentially, and the degree of gelling of the doping inks and doping ink gels formed can be controlled specifically and influenced in the desired manner as a consequence of the condensation conditions set, such as precursor concentrations, water content, catalyst content, reaction temperature and time, the addition of condensation-controlling agents, such as, for example, various above-mentioned complexing agents and chelating agents, various solvents and individual volume fractions thereof, and also the specific elimination of readily volatile reaction assistants and disadvantageous by-products, giving storage-stable, very readily printable and printing-stable formulations.

In particular, the printable boron doping pastes according to the invention comprise at least one classical polymeric thickening substance, where these rheology-influencing substances are selected from the group polyvinylpyrrolidone, polyvinyl alcohol, polyvinyl acetate, polyvinylimidazole, polyvinylbutyral, methylcelluloses, ethylcelluloses, hydroxyethylcelluloses, hydroxypropylcelluloses, microcrystalline celluloses, sodium starch glycolates, xanthan and gellan gum, gelatine, agar, alginic acid and alginates, guar flour, pectin, carubin, polyacrylic acids, polyacrylates, associatively thickening polyurethanes, and mixtures thereof, where, however, polyvinylpyrrolidone, polyvinyl acetate, polyvinylbutyral and ethylcellulose and mixtures thereof are particularly preferred.

These printable boron doping pastes are prepared using polymeric thickening substances, where these interact associatively and thus in a structure-forming manner with parts of the hybrid sol via, for example, coordinative and chelating mechanisms and thus result in significantly more pronounced structural viscosity than through the use of polymeric thickening compounds alone.

In particular, the present invention relates to printable boron doping pastes which are prepared using aluminium hydroxides and aluminium oxides, colloidally precipitated or highly disperse silicon dioxide, tin dioxide, boron nitride, silicon carbide, silicon nitride, aluminium titanate, titanium dioxide, titanium carbide, titanium nitride, titanium carbonitride as particulate formulation assistants which modify the rheology and also have a positive influence on the layer thickness of the dried paste.

These boron doping pastes can be processed and deposited on the surfaces to be treated by printing processes such as spin or dip coating, drop casting, curtain or slot-die coating, screen or flexographic printing, gravure, ink-jet or aerosol-jet printing, offset printing, microcontact printing, electrohydrodynamic dispensing, roller or spray coating, ultrasound spray coating, pipe-jet printing, laser transfer printing, pad printing, flat-bed screen printing and rotational screen printing, but particularly preferably by means of flatbed screen printing.

Printable boron doping pastes corresponding to Claims 1 to 6 as doping media for the treatment of silicon wafers for photovoltaic, microelectronic, micromechanical and micro-optical applications.

The printable boron doping pastes provided hereby are particularly suitable for the production of PERC, PERL, PERT and IBC solar cells and others, where the solar cells have further architectural features, such as MWT, EWT, selective emitter, selective front surface field, selective back surface field and bifaciality.

In particular, the novel printable boron doping pastes described here are suitable both for acting as boron-containing doping medium on silicon and also as diffusion barrier or as diffusion-inhibiting layer against the diffusion of phosphorus through these media themselves and completely blocking or inhibiting this to an adequate extent, so that the doping prevailing beneath these printed-on media is p type, i.e. boron-containing.

It has proven particularly advantageous that the printable boron doping pastes according to the invention induce, through suitable temperature treatment, doping of the printed substrate and simultaneously and/or sequentially doping of the unprinted silicon wafer surfaces with dopants of the opposite polarity by means of conventional gas-phase diffusion, where the printed-on boron doping pastes act as diffusion barrier against the dopants of the opposite polarity.

In accordance with the invention, a process for the production of solar cells using the printable boron doping pastes described here is characterised in that
a) silicon wafers are printed locally on one or both sides or over the entire surface on one side with the boron doping pastes, the pastes are dried, compacted, and the silicon wafers are subsequently subjected to subsequent gas-phase diffusion with, for example, phosphoryl chloride, giving p-type dopings in the printed regions and n-type dopings in the regions subjected exclusively to gas-phase diffusion, or
b) boron doping paste printed over a large area onto the silicon wafer is compacted, and local doping of the underlying substrate material is initiated from the dried and/or compacted paste with the aid of laser irradiation, followed by high-temperature diffusion and doping for the production of two-stage p-type doping levels in the silicon, or
c) the silicon wafer is printed locally on one side with boron doping pastes, where the structured deposition may optionally have alternating lines, the printed structures are dried and compacted, and the silicon wafer is subsequently coated over the entire surface on the same side of the wafer with the aid of PVD- and/or CVD-deposited phosphorus-doping dopant sources, where the printed structures of the boron doping pastes are encapsulated, and the entire overlapping structure is brought to structured doping of the silicon wafer by suitable high-temperature treatment, where the printed-on boron paste acts as diffusion barrier against the phosphorus-containing dopant source located on top and the dopant present therein, or
d) the silicon wafer is printed locally on one side with boron doping pastes, where the structured deposition may optionally have alternating lines, the printed structures are dried and compacted, and the silicon wafer is subsequently coated over the entire surface on the same side of the wafer with the aid of phosphorus-doping doping inks or doping pastes, where the printed structures of the boron doping pastes are encapsulated, and the entire overlapping structure is brought to structured doping of the silicon wafer by suitable high-temperature treatment, where the printed-on boron paste acts as diffusion barrier against the phosphorus-containing dopant source located on top and the dopant present therein, or
e) the silicon wafer is printed locally on one side with boron doping pastes, where the structured deposition may optionally have alternating lines, the printed structures are dried and compacted, and the silicon wafer is subsequently printed on the same side of the wafer with a negative structure compared with the preceding print with the aid of a phosphorus paste, and the entire structure is brought to structured doping of the silicon wafer on one side and over the entire surface of the opposite side by suitable high-temperature treatment in the presence of a conventional phosphorus-based gas-phase diffusion source, such as, for example, phosphoryl chloride, where the printed-on boron paste acts as diffusion barrier against the other phosphorus-containing diffusion sources present at the same time, or
f) the silicon wafer is printed locally on one side with boron doping pastes, where the structured deposition may optionally have alternating lines, the printed structures are dried and compacted, and the silicon wafer is subsequently printed on the same side of the wafer with a negative structure compared with the preceding print with the aid of a phosphorus paste, the opposite side of the same wafer is subsequently printed with a further phosphorus doping paste, where the sequence of the printing steps of application of the phosphorus doping pastes need not necessarily take place in the said series, and the entire structure is brought to structured doping of the silicon wafer on one side and over the entire surface of the opposite side by suitable high-temperature treatment, where the printed-on boron paste acts as diffusion barrier against the other phosphorus-containing diffusion sources present at the same time.

### DETAILED DESCRIPTION OF THE INVENTION

Surprisingly, it has been found that boron-containing doping inks prepared on the basis of the sol-gel process can be formulated with the aid of classical thickeners in such a way that very readily printable formulations can be obtained therefrom. Suitable printing processes which may be considered are at least those mentioned below: spin or dip coating, drop casting, curtain or slot-die coating, screen or flexographic printing, gravure, ink-jet or aerosol-jet printing, offset printing, microcontact printing, electrohydrodynamic dispensing, roller or spray coating, ultrasound spray coating, pipe-jet printing, laser transfer printing, pad printing, flat-bed screen printing and rotational screen printing. The boron-containing doping inks formulated further into pastes are preferably, but not exclusively, printed onto silicon surfaces with the aid of the screen-printing process. The boron-containing doping inks are prepared here with the aid of the sol-gel process and consist at least of oxide precursors of the following oxides: aluminium oxide, silicon dioxide and boron oxide. The mixing ratios of the oxide precursors mentioned may be present in randomly selected proportions. Typical precursors of the oxides for the preparation of the boron-containing doping inks according to the invention, but not exclusively restricted to the said examples, which are also referred to as hybrid sols below, are presented below:

Aluminium oxide: symmetrically and asymmetrically substituted aluminium alcoholates (alkoxides), such as aluminium triethanolate, aluminium triisopropylate, aluminium tri-sec-butylate, aluminium tributylate, aluminium triamylate and aluminium triisopentanolate, aluminium tris(β-diketones), such as aluminium acetylacetonate or aluminium tris(1,3-cyclohexanedionate), aluminium tris(β-ketoesters), aluminium monoacetylacetonate monoalcoholate, aluminium tris(hydroxyquinolate), aluminium soaps, such as mono- and dibasic aluminium stearate and aluminium tristearate, aluminium carboxylates, such as basic aluminium acetate, aluminium triacetate, basic aluminium formate, aluminium triformate and aluminium trioctanoate, aluminium hydroxide, aluminium metahydroxide and aluminium trichloride and the like, and mixtures thereof.

Silicon dioxide: symmetrically and asymmetrically mono- to tetrasubstituted carboxy-, alkoxy- and alkoxyalkylsilanes, explicitly containing alkylalkoxysilanes, in which the central silicon atom can have a degree of substitution of [lacuna] by at least one hydrogen atom bonded directly to the silicon atom, such as, for example, triethoxysilane, and where furthermore a degree of substitution relates to the number of possible carboxyl and/or alkoxy groups present, which, both in the case of alkyl and/or alkoxy and/or carboxyl groups, contain individual or different saturated, unsaturated branched, unbranched aliphatic, alicyclic and aromatic radicals, which may in turn be functionalised at any desired position of the alkyl, alkoxide or carboxyl radical by heteroatoms selected from the group O, N, S, Cl and Br, and mixtures of the above-mentioned precursors; individual compounds which satisfy the above-mentioned demands are: tetraethyl orthosilicate and the like, triethoxysilane, ethoxytrimethylsilane, dimethyldimethoxysilane, dimethyldiethoxysilane, triethoxyvinylsilane, bis[triethoxysilyl]ethane and bis[diethoxymethylsilyl]ethane.

Boron oxide: diboron oxide, simple alkyl borates, such as triethyl borate, triisopropyl borate, boric acid esters of functionalised 1,2-glycols, such as, for example, ethylene glycol, functionalised 1,2,3-triols, such as, for example, glycerol, functionalised 1,3-glycols, such as, for example, 1,3-propanediol, boric acid esters with boric acid esters which contain the above-mentioned structural motifs as structural sub-units, such as, for example, 2,3-dihydroxy-succinic acid and enantiomers thereof, boric acid esters of ethanolamine, diethanolamine, triethanolamine, propanolamine, dipropanolamine and tripropanolamine, mixed anhydrides of boric acid and carboxylic acids, such as, for example, tetraacetoxy diborate, boric acid, metaboric acid, and mixtures of the above-mentioned precursors.

The possible combinations are furthermore not necessarily restricted to the above-mentioned possible compositions: further substances which are able to impart advantageous properties on the sols may be present as additional components in the hybrid sols. They may be: oxides, basic oxides, hydroxides, alkoxides, carboxylates, β-diketonates, β-ketoesters, silicates and the like of cerium, tin, zinc, titanium, zirconium, hafnium, zinc, germanium, gallium, niobium, yttrium, which can be used directly or in pre-condensed form in the sol-gel synthesis. The hybrid sols are sterically stabilised by the use of complexing and chelating substances, which may also control the condensation behaviour of the oxide precursors, in particular of aluminium, and also of other metal cations. Substances which are suitable in this respect are, for example, acetylacetone, 1,3-cyclohexanedione, isomeric compounds of dihydroxybenzoic acids, acetaldoxime, and in addition also those disclosed and present in the patent applications WO 2012/119686 A, WO2012119685 A1, WO2012119684 A, EP12703458.5 and EP12704232.3. The contents of these specifications are therefore incorporated into the disclosure content of the present application. The hybrid sols can be prepared with the aid of an anhydrous or water-containing sol-gel synthesis. In addition, further assistants can be used in the formulation of the hybrid sols according to the invention to form screen-printable pastes. Such assistants may be:
surfactants, tensioactive compounds for influencing the wetting and drying behaviour,
antifoams and deaerators for influencing the drying behaviour,
strong carboxylic acids for initiation of the condensation reaction of oxide precursors, at least the following may serve as suitable carboxylic acids: formic acid, acetic acid, oxalic acid, trifluoroacetic acid, mono-, di- and trichloroacetic acid, glyoxalic acid, tartaric acid, maleic acid, malonic acid, pyruvic acid, malic acid, 2-oxoglutaric acid,
high- and low-boiling non-polar and also polar protic and aprotic solvents for influencing the particle size distribution, the degree of pre-condensation, the condensation, wetting and drying behaviour and the printing behaviour, where these may be: glycols, glycol ethers, glycol ether carboxylates, polyols, terpineol, Texanol, butyl benzoate, benzyl benzoate, dibenzyl ether, butyl benzyl phthalate and others, and mixtures thereof,
particulate additives for influencing the rheological properties,
particulate additives (for example aluminium hydroxides and aluminium oxides, colloidally precipitated or highly disperse silicon dioxide, tin dioxide, boron nitride, silicon carbide, silicon nitride, aluminium titanate, titanium dioxide, titanium carbide, titanium nitride, titanium carbonitride) for influencing the dry-film thicknesses resulting after drying and the morphology thereof,
particulate additives (for example aluminium hydroxides and aluminium oxides, colloidally precipitated or highly disperse silicon dioxide, tin dioxide, boron nitride, silicon carbide, silicon nitride, aluminium titanate, titanium dioxide, titanium carbide, titanium nitride, titanium carbonitride) for influencing the scratch resistance of the dried films,
capping agents selected from the group acetoxytrialkylsilanes, alkoxytrialkylsilanes, halotrialkylsilanes and derivatives thereof for influencing the condensation rates and the storage stability,
waxes and wax-like compounds, such as beeswax, Syncrowax, lanolin, carnauba wax, jojoba, Japan wax and the like, fatty acids and fatty alcohols, fatty glycols, esters of fatty acids and fatty alcohols, triglycerides, fatty aldehydes, fatty ketones and fatty β-diketones and mixtures thereof, where the above-mentioned classes of substance should each contain branched and unbranched carbon chains having chain lengths greater than or equal to twelve carbon atoms,
polymeric thickening, rheology-modifying additives, such as, for example, polyvinylpyrrolidone, polyvinyl alcohol, polyvinyl acetate, polyvinylimidazole, polyvinylbutyral, methylcelluloses, ethylcelluloses, hydroxyethylcelluloses, hydroxypropylcelluloses, microcrystalline celluloses, sodium starch glycolates, xanthan and gellan gum, gelatine, agar, alginic acid and alginates, guar flour, pectin, carubin, polyacrylic acids, polyacrylates, associatively thickening polyurethanes, and mixtures thereof.

One synthetic method is based on the dissolution of oxide precursors of aluminium oxide in a solvent or solvent mixture, preferably selected from the group high-boiling glycol ethers or preferably high-boiling glycol ethers and alcohols, to which a suitable acid, preferably a carboxylic acid, and here particularly preferably formic acid or acetic acid, is subsequently added, and which is completed by the addition of suitable complexing agents and chelating agents, such as, for example, suitable β-diketones, such as acetylacetone or, for example, 1,3-cyclohexanedione, α- and β-ketocarboxylic acids and esters thereof, such as, for example, pyruvic acid and esters thereof, acetoacetic acid and ethyl acetoacetate, isomeric dihydroxybenzoic acids, such as, for example, 3,5-dihydroxybenzoic acid, and/or oximes, such as, for example, acetaldoxime, and further cited compounds of this type, and also any desired mixtures of the above-mentioned complexing agents, chelating agents and agents which control the degree of condensation. A mixture consisting of the above-mentioned solvent or solvent mixture and water is then added dropwise to the solution of the aluminium oxide precursor at room temperature, and the mixture is subsequently warmed under reflux at 80° C. for up to 24 h. Gelling of the aluminium oxide precursor can be controlled specifically via the molar ratio of the aluminium oxide precursor to water, to the acid used and also the molar amounts and type of the complexing agents employed. The synthesis durations necessary in each case are likewise dependent on the above-mentioned molar ratios. The readily volatile and desired parasitic by-products occurring in the reaction are subsequently removed from the finished reaction mixture, which is optionally already furthermore diluted, by means of vacuum distillation. The vacuum distillation is achieved by stepwise reduction of the final pressure to 30 mbar at a constant temperature of 70° C. The hybrid gels are adjusted with respect to their desired properties, either after or even before the distillative treatment, by specific addition of suitable solvents which favour the rheology and printability of the paste, such as, for example, high-boiling glycols, glycol ethers, glycol ether carboxylates and furthermore solvents such as terpineol, Texanol, butyl benzoate, benzyl benzoate, dibenzyl ether, butyl benzyl phthalate, and solvent mixtures, and optionally diluted. In parallel to the dilution and adjustment of the paste properties, a mixture consisting of condensed oxide precursors of silicon dioxide and boron oxide is added. For this purpose, precursors of boron oxide are initially introduced in a solvent, such as, for example, dibenzyl ether, butyl benzyl phthalate, benzyl benzoate, butyl benzoate, THF or a comparable solvent, a suitable carboxylic anhydride, such as, for example, acetic anhydride, formyl acetate or propionic anhydride or a comparable anhydride, is added, and dissolved or brought to reaction under reflux until a clear solution is present. Suitable precursors of silicon dioxide, optionally pre-dissolved in the reaction solvent used, are added dropwise to this solution. The reaction mixture is subsequently warmed or refluxed for up to 24 h. After the mixing of all components, the paste rheology can furthermore be adjusted and rounded off in accordance with specific requirements corresponding to the assistants and additives likewise already described in detail above, where the use according to the invention of the said polymeric thickeners has a particular role. The thickeners are stirred into the mixture with vigorous stirring, where the stirring duration is dependent on the respective thickener used. The stirring-in of the thickener can optionally be completed with a vacuum treatment step, during which air bubbles stirred into the highly viscous mass are removed. Depending on the thickeners used, the resultant paste may have to be left to swell for a period of up to three days.

An alternative synthetic method is based on the preparation of a condensed sol of oxide precursors of silicon dioxide and boron oxide. For this purpose, precursors of boron oxide are initially introduced in a solvent, such as, for example, dibenzyl ether, butyl benzyl phthalate, benzyl benzoate, butyl benzoate, THF or a comparable solvent, a suitable carboxylic anhydride, such as, for example, acetic anhydride, formyl acetate or propionic anhydride or a comparable anhydride, is added and dissolved or brought to reaction under reflux until a clear solution is present. Suitable precursors of silicon dioxide, optionally pre-dissolved in the reaction solvent used, are added dropwise to this solution. The reaction mixture is subsequently warmed or refluxed for up to 24 h. Suitable solvents, such as, for example, glycols, glycol ethers, glycol ether carboxylates and furthermore solvents such as terpineol, Texanol, butyl benzoate, benzyl benzoate, dibenzyl ether, butyl benzyl phthalate, or solvent mixtures thereof, in which suitable complexing agents and chelating agents, such as, for example, suitable β-diketones, such as acetylacetone or, for example, 1,3-cyclohexanedione, α- and β-ketocarboxylic acids and esters thereof, such as, for example, pyruvic acid and esters thereof, acetoacetic acid and ethyl acetoacetate, isomeric dihydroxybenzoic acids, such as, for example, 3,5-dihydroxybenzoic acid, and/or oximes, such as, for example, acetaldoxime, and further cited compounds of this type, and also any desired mixtures of the above-mentioned complexing agents, chelating agents and agents which control the degree of condensation, which are already predissolved in the presence of water, are subsequently added to the sol, and the mixture is stirred, where the temperature of the reaction mixture may increase at the same time. The duration of mixing of the two solutions can be between 0.5 minute and five hours. The entire mixture is heated with the aid of an oil bath, whose temperature is generally set to 155° C. After a duration of mixing of the entire solution completed from the two part-solutions which is known as suitable, a suitable aluminium oxide precursor, which has itself been pre-dissolved in one of the above-mentioned solvents or solvent mixtures, is subsequently added dropwise or allowed to run into the reaction mixture in such a way that the addition is completed in a time window of five minutes since the beginning of the addition. The reaction mixture now completed in this way is then warmed under reflux for one to four hours. The warm gelled mixture can then be modified further with respect to its Theological properties using further assistants already mentioned above, in particular and particularly preferably, however, through the use of the polymeric thickeners to be used in accordance with the invention. The thickeners are stirred into the mixture here with vigorous stirring, where the stirring duration is dependent on the respective thickener used. The stirring-in of the thickener can optionally be completed with a vacuum treatment step, during which air bubbles stirred into the highly viscous mass are removed. Depending on the thickeners used, the resultant paste may have to be left to swell for a period of up to three days.

Surprisingly, it has been found here that the polymers used during paste formulation can advantageously interact associatively with the constituents present in the hybrid sol. This interaction is based on coordination or chelate complex formation between the polymers stirred in for formulation and also the constituents present in the hybrid sol, in this case preferably those of aluminium.

In the following examples, the preferred embodiments of the present invention are reproduced.

As stated above, the present description enables the person skilled in the art to use the invention comprehensively. Even without further comments, it will therefore be assumed that a person skilled in the art will be able to utilise the above description in the broadest scope.

Should anything be unclear, it goes without saying that the cited publications and patent literature should be consulted. Accordingly, these documents are regarded as part of the disclosure content of the present description.

For better understanding and in order to illustrate the invention, examples are given below which are within the scope of protection of the present invention. These examples also serve to illustrate possible variants. Owing to the general validity of the inventive principle described, however, the examples are not suitable for reducing the scope of protection of the present invention to these alone.

Furthermore, it goes without saying to the person skilled in the art that, both in the examples given and also in the remainder of the description, the component amounts present in the compositions always only add up to 100% by weight, mol-% or vol.-%, based on the entire composition, and cannot exceed this, even if higher values could arise from the percent ranges indicated. Unless indicated otherwise, % data are therefore regarded as % by weight, mol-% or vol.-%.

The temperatures given in the examples and description and in the claims are always in ° C.

### EXAMPLES

### Example 1

8 g of boron oxide were initially introduced in a glass flask and suspended in 80 g of acetic anhydride and 160 g of tetrahydrofuran. The mixture was brought to reflux, and 24.2 g of ethylene glycol monobutyl ether (EGB) were added. 24.2 g of diethoxydimethylsilane and 31 g of dimethyldimethoxysilane were subsequently added to the refluxing mixture, and this was warmed with boiling for 30 minutes. A solution consisting of 480 g of EGB and 250 g of Texanol, in which 2.5 g of water, 2 g of 1,3-cyclohexanedione and 4.2 g of acetaldoxime were dissolved, was added to the siloxane-containing solution and allowed to mix for 20 minutes. Over the same period, the reaction temperature was increased from 80° C. to 120° C. After the mixing, 50 g of aluminium tri-sec-butylate, dissolved in 400 g of dibenzyl ether, were allowed to run into the reaction mixture over the course of five minutes, and the completed mixture was left to react for a further 55 minutes. The reaction mixture was then freed from readily volatile solvents and reaction products by vacuum distillation at 70° C. until a final pressure of 30 mbar had been reached. Various pasty mixtures were prepared from the boron-containing doping ink by stirring in ethylcellulose.

TABLE 1
Mixtures of boron-containing doping inks subsequently
thickened using ethylcellulose. Mixtures from a mass
proportion between 2.9% and 3.4% were readily screen-
printable. Paste mixtures having a mass proportion >5% of
ethylcellulose were no longer printable.

| Mass of | Mass of | |
|---|---|---|
| boron ink | ethylcellulose | Mass proportion of |
| [g] | [g] | ethylcellulose [%] |
| 200 | 2 | 0.99 |
| 200 | 3 | 1.48 |
| 200 | 4 | 1.96 |
| 200 | 5 | 2.44 |
| 200 | 6 | 2.91 |
| 200 | 7 | 3.38 |
| 200 | 8 | 3.85 |
| 200 | 9 | 4.31 |
| 200 | 10 | 4.76 |

### Example 2

A paste in accordance with Example 1, characterised by a mass proportion of 4.3% of ethylcellulose, was printed onto a silicon wafer surface using a 350 mesh screen having a wire diameter of 16 μm, an emulsion thickness of 8 μm to 12 μm, and furthermore using a squeegee speed of 200 mm/s and a squeegee pressure of 1 bar, and subsequently subjected to drying in a through-flow oven using the following heating zone temperatures: 350/350/375/375/375/400/400° C.

Paste mixtures having a mass proportion of greater than 5% and also those having a mass proportion of less than 2.5% cannot be processed by means of the screen printing process.

FIG. 2: shows a silicon wafer printed with the aid of a boron-containing doping paste according to the invention and in accordance with the composition and preparation of Example 1, after drying in a through-flow oven. The different colours (→ interference colours) correspond to differences in locally present glass film thicknesses. Optimisation of the printing process results in a more homogeneous colour appearance of the printed wafer.

### Example 3

4 g of boron oxide were initially introduced in a glass flask and suspended in 40 g of acetic anhydride and 80 g of tetrahydrofuran. The mixture was brought to reflux, and 11.25 g of ethylene glycol monobutyl ether (EGB) were added. 12.1 g of diethoxydimethylsilane and 15.1 g of dimethyldimethoxysilane were subsequently added to the refluxing mixture, and this was warmed with boiling for 30 minutes. 32.5 g of the siloxane-containing solution were mixed with 69.8 g of a solution consisting of 240 g of EGB and 125 g of Texanol, and the heating temperature was increased from 80° C. to 120° C. over the course of 20 minutes with stirring of the reaction mixture. 1.75 g of 1,3-cyclohexanedione, 0.75 g of acetaldoxime and 0.5 g of water were dissolved in the reaction mixture. 10 g of aluminium tri-sec-butylate dissolved in 40 g of dibenzyl ether were subsequently added dropwise to the reaction mixture over the course of five minutes. After the addition, the mixture was left to react for a further 55 minutes. The reaction mixture was then subjected to vacuum distillation at 70° C. until a final pressure of 30 mbar had been reached in order to free the mixture from readily volatile solvents and reaction products. A mass loss of 31.74 g was determined here. Various pasty mixtures were prepared from the boron-containing doping ink by stirring in ethylcellulose: to this end, 5.1 g of ethylcellulose were stirred into 106.1 g of the doping ink. The paste was left to rest overnight after the stirring.

### Example 4

The paste according to the invention in accordance with Example 3 was printed onto an alkaline-etched n-type CZ wafer with the aid of a 400 mesh screen having a wire diameter of 18 μm. The other printing parameters corresponded to those which have already been described in Example 2(likewise the layout used). The printed wafer was coated by spray coating with the aid of a phosphorus-containing doping ink, and the wafer was subsequently subjected to a co-diffusion process at 935° C. for 30 minutes, followed by oxidation for five minutes in dry synthetic air, furthermore followed by a further drive-in step of 15 minutes. The boron-doped region was investigated by means of secondary ion mass spectrometry (SIMS). The principal doping of the wafer corresponded to p-doping with boron.

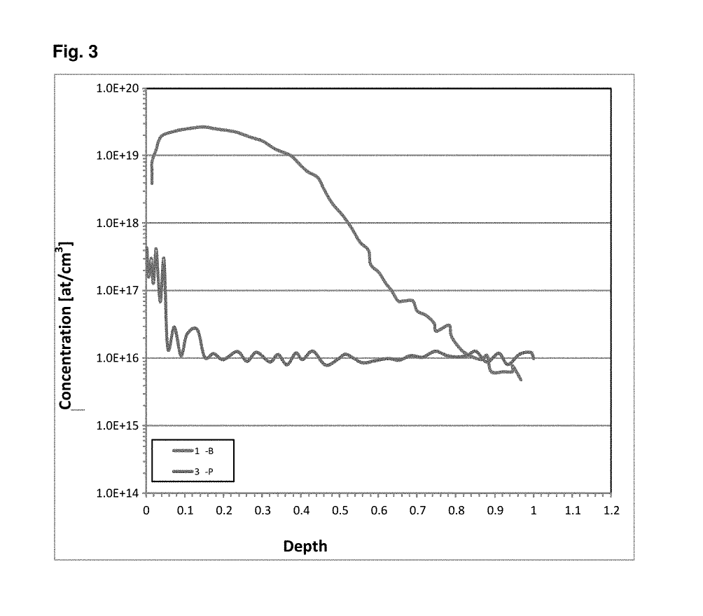

FIG. 3: shows SIMS doping profiles of an alkaline-etched n-type CZ wafer, printed with a doping paste according to the invention in accordance with Example 3. The doped structure has exclusively intense boron doping. The phosphorus doping corresponds to the background doping of the n-type wafer.

### Example 5

Pastes according to the invention in accordance with Example 1 were investigated with respect to their dynamic viscosity with the aid of a cone-and-plate rheometer. The pastes had non-Newtonian flow properties.

TABLE 2
Dynamic viscosity of pastes according to the invention
in accordance with Example 1.

| | | | Dynamic |
|---|---|---|---|
| | | Mass | viscosity |
| Mass of | Mass of | proportion of | (forwards/ |
| boron ink | ethylcellulose | ethylcellulose | backwards)¹ |
| [g] | [g] | [%] | [Pa * s] |
| 200 | 9 | 4.31 | 26.1/23.5 |
| 200 | 10 | 4.76 | 24.4/29.2 |

¹Forwards and backwards curve.

In a separate batch, 150 g of ethylene glycol monobutyl ether, 75.9 g of Texanol and 121.9 g of dibenzyl ether were mixed. The viscosity of the solvent mixture was 3.47 mPa*s. In one case 3.5 g of Ethocel and in the second case 4.5 g of Ethocel were stirred into 100 g of the solvent in each case. Furthermore, the dynamic viscosity of the boron-containing doping ink was determined in accordance with Example 1. All media investigated exhibited Newtonian flow properties.

TABLE 3
Dynamic viscosity of pastes according to the invention in
accordance with Example 1.

| | Mass of | Mass proportion | Dynamic |
|---|---|---|---|
| | ethylcellulose | of ethylcellulose | viscosity |
| | [g] | [%] | [mPa * s] |
| Solvent mixture | 0.0 | 0.00 | 3.47 |
| Solvent mixture | 3.5 | 3.38 | 204 |
| Solvent mixture | 4.5 | 4.31 | 591 |
| Boron ink | 0.0 | 0.00 | 15.65 |

It becomes clear from a comparison of Tables 2 and 3 that the addition of the thickener to the solvent mixture in which the hybrid sols are dissolved allows the viscosity of the mixture to increase. Without an interaction with the active components of the hybrid sol, an increase in the viscosity to ˜600 mPas would be expected. By contrast, a corresponding paste mixture having the same mass proportion of ethylcellulose exhibits a dynamic viscosity of 26.1 Pa*s, i.e. approximately 45 times the expected value. For this reason, it can be assumed that the thickeners used in these examples undergo an associative interaction with parts of the hybrid sol, causing the structure formation taking place in the solution to be significantly increased compared with the structure formation taking place in the pure solvent mixture. This structure formation can be explained by means of complex and chelate complex formation of the polymer with the aluminium cores present in the hybrid sol.

1. A printable boron doping paste or gel based on a precursor of silicon dioxide, aluminium oxide or boron oxide, comprising
at least one polymer as thickener selected from the group consisting of polyvinylpyrrolidone, polyvinyl alcohol, polyvinyl acetate, polyvinylimidazole, polyvinylbutyral, methylcellulose, ethylcellulose, hydroxyethylcellulose, hydroxypropylcellulose, microcrystalline cellulose, sodium starch glycolate, xanthan gum, gellan gum, gelatine, agar, alginic acid, alginates, guar flour, pectin, carubin, polyacrylic acid, polyacrylate, associatively thickening polyurethane and a mixture thereof, which can be employed for local and/or full-area diffusion and doping on one side in solar cell production processes, and
which paste or gel has been obtained from a precursor of silicon dioxide, aluminium oxide or boron oxide, or a mixture thereof,
wherein
the precursor of silicon dioxide is
a symmetrically or asymmetrically mono- to tetrasubstituted carboxy-, alkoxy- or alkoxyalkylsilane, in which at least one hydrogen atom is bonded to the central silicon atom, or
carboxy-, alkoxy- or alkoxyalkylsilane, which contain individual or different saturated, unsaturated branched, unbranched aliphatic, alicyclic or aromatic radicals, which are optionally functionalised at a position of the alkyl, alkoxide or carboxyl radical by one or more heteroatoms selected from the group consisting of O, N, S, Cl and Br, or
tetraethyl orthosilicate, triethoxysilane, ethoxytrimethylsilane, dimethyldimethoxysilane, dimethyldiethoxysilane, triethoxyvinylsilane, bis[triethoxysilyl]ethane or bis[diethoxymethylsilyl]ethane,
or a mixture thereof;
the precursor of aluminum oxide is
a symmetrically or asymmetrically substituted aluminium alcoholate (alkoxide), aluminium tris(β-diketone), aluminium tris(β-ketoester), an aluminium soap, an aluminium carboxylate, or
aluminium triethanolate, aluminium triisopropylate, aluminium tri-sec-butylate, aluminium tributylate, aluminium triamylate, aluminium triisopentanolate, aluminium acetyl-acetonate or aluminium tris(1,3-cyclohexanedionate), aluminium monoacetylacetonate monoalcoholate, aluminium tris(hydroxyquinolate), mono- or dibasic aluminium stearate or aluminium triformate or aluminium trioctanoate, aluminium hydroxide, aluminium metahydroxide or aluminium trichloride,
or a mixture thereof;
the precursor of boron oxide is
an alkyl borate, a boric acid ester of a functionalised 1,2-glycol, a boric acid ester of an alkanolamine, a mixed anhydride of boric acid or carboxylic acid, or
boron oxide, diboron oxide, triethyl borate, triisopropyl borate, boric acid glycol ester, boric acid ethylene glycol ester, boric acid glycerol ester, boric acid ester of 2,3-dihydroxy-succinic acid, tetraacetoxy diborate and boric acid esters of the alkanolamines ethanolamine, diethanolamine, triethanolamine, propanolamine, dipropanolamine or tripropanolamine,
or a mixture thereof.

2. The printable boron doping paste according to claim 1, comprising at least one polymer as thickener selected from the group consisting of polyvinylpyrrolidone, polyvinyl acetate, polyvinylbutyral, ethylcellulose and a mixture thereof.

3. The printable boron doping paste according to claim 1, comprising at least one polymer as thickener which interacts associatively and thus in a structure-forming manner with constituents of a hybrid sol and causes a significantly more pronounced structural viscosity than comparable pastes which comprise only polymeric thickening compounds.

4. The printable boron doping paste according to claim 1, comprising at least one polymer as thickener which interacts with constituents of a hybrid sol via coordinative and/or chelating mechanisms.

5. The printable boron doping paste according to claim 1, comprising additives selected from the group consisting of aluminium hydroxides, aluminium oxides, colloidally precipitated silicon dioxide, highly disperse silicon dioxide, tin dioxide, boron nitride, silicon carbide, silicon nitride, aluminium titanate, titanium dioxide, titanium carbide, titanium nitride, titanium carbonitride, and particulate formulation assistants which have a positive influence on the layer thickness of a dried paste.

6. The printable boron doping paste according to claim 1, which is based on a precursor of silicon dioxide, aluminium oxide or boron oxide.

7. The printable doping paste according to claim 1, which is based on a mixture of precursors of silicon dioxide, aluminium oxide and boron oxide.

8. The printable boron doping paste according to claim 1, which has been obtained on the basis of a precursor of silicon dioxide, which is
a symmetrically or asymmetrically mono- to tetrasubstituted carboxy-, alkoxy- or alkoxyalkylsilane in which at least one hydrogen atom is bonded to the central silicon atom,
carboxy-, alkoxy- or alkoxyalkylsilane which contain individual or different saturated, unsaturated branched, unbranched aliphatic, alicyclic or aromatic radicals, which are optionally functionalised at a position of the alkyl, alkoxide or carboxyl radical by one or more heteroatoms selected from the group consisting of O, N, S, Cl and Br,
or a mixture thereof.

9. The printable boron doping paste according to claim 1, which has been obtained on the basis of a precursor of silicon dioxide, which is tetraethyl orthosilicate, triethoxysilane, ethoxytrimethylsilane, dimethyldimethoxysilane, dimethyldiethoxysilane, triethoxyvinylsilane, bis[triethoxysilyl]ethane or bis[diethoxymethylsilyl]ethane, or a mixture thereof.

10. The printable boron doping paste according to claim 1, which has been obtained on the basis of a precursor of aluminium oxide, which is a symmetrically or asymmetrically substituted aluminium alcoholate (alkoxide), aluminium tris(β-diketone), aluminium tris(β-ketoester), an aluminium soap, an aluminium carboxylate or a mixture thereof.

11. The printable boron doping paste according to claim 1, which has been obtained on the basis of a precursor of aluminium oxide, which is aluminium triethanolate, aluminium triisopropylate, aluminium tri-sec-butylate, aluminium tributylate, aluminium triamylate, aluminium triisopentanolate, aluminium acetylacetonate or aluminium tris(1,3-cyclohexanedionate), aluminium monoacetylacetonate monoalcoholate, aluminium tris(hydroxyquinolate), mono- or dibasic aluminium stearate or aluminium tristearate, aluminium acetate, aluminium triacetate, basic aluminium formate, aluminium triformate or aluminium trioctanoate, aluminium hydroxide, aluminium metahydroxide or aluminium trichloride, or a mixture thereof.

12. The printable boron doping paste according to claim 1, which has been obtained on the basis of a precursor of boron oxide, which is selected from the group consisting of alkyl borates, boric acid esters of functionalised 1,2-glycols, boric acid esters of alkanolamines, mixed anhydrides of boric acid and carboxylic acids, and mixtures thereof.

13. The printable boron doping paste according to claim 1, which has been obtained on the basis of a precursor of boron oxide, which is selected from the group consisting of boron oxide, diboron oxide, triethyl borate, triisopropyl borate, boric acid glycol ester, boric acid ethylene glycol ester, boric acid glycerol ester, boric acid ester of 2,3-dihydroxysuccinic acid, tetraacetoxy diborate and boric acid esters of the alkanolamines ethanolamine, diethanolamine, triethanolamine, propanolamine, dipropanolamine and tripropanolamine.

14. The printable boron doping paste according to claim 1, obtainable by bringing precursors to partial or complete intra- and/or interspecies condensation under water-containing or anhydrous conditions with the aid of the sol-gel technique, either simultaneously or sequentially, forming storage-stable, readily printable and printing-stable formulations.

15. The printable boron doping paste according to claim 14, obtainable by removal of volatile reaction assistants and by-products during the condensation reaction.

16. The printable boron doping paste according to claim 14, obtainable by adjustment of the precursor concentration, the water and catalyst content and the reaction temperature and time.

17. The printable boron doping paste according to claim 14, obtainable by addition of one or more condensation-controlling agents in the form of complexing agents and/or chelating agents, one or more solvents in predetermined amounts, based on the total volume, wherein the degree of gelling of the hybrid sols and gels formed is controlled.

18. A process for the production of solar cells, in which the printable boron doping paste according to claim 1 is printed onto silicon surfaces for the purposes of local and/or full-area diffusion and doping on one side by a printing process in the production of solar cells, optionally of highly efficient solar cells doped in a structured manner, and dried and subsequently brought to specific doping of the substrate by a suitable high-temperature process for release of the boron oxide precursor present in the dried paste to the substrate located beneath the boron paste.

19. A process for the production of solar cells, in which the printable boron doping paste according to claim 1 is processed and deposited by a printing process selected from spin or dip coating, drop casting, curtain or slot-die coating, screen or flexographic printing, gravure, ink-jet or aerosol-jet printing, offset printing, microcontact printing, electrohydrodynamic dispensing, roller or spray coating, ultrasound spray coating, pipe-jet printing, laser transfer printing, pad printing, flat-bed screen printing and rotational screen printing.

20. A process according to claim 24, wherein the silicon wafers are for photovoltaic, microelectronic, micromechanical or micro-optical applications.

21. A process according to claim 18, which is for the production of a product selected from the group consisting of PERC, PERL, PERT and IBC solar cells and comparable solar cells, where the solar cells have further architectural features, MWT, EWT, selective emitter, selective front surface field, selective back surface field and bifacial solar cells.

22. A process for boron doping of silicon, comprising achieving said doping with the printable boron doping paste according to claim 1, where the medium simultaneously acts as diffusion barrier or as diffusion-inhibiting layer against undesired diffusion of phosphorus through this medium and completely blocks or inhibits the latter to an adequate extent, so that the doping prevailing beneath these printed-on media is p type, i.e. boron-containing.

23. A process according to claim 22, wherein the doping of the printed substrate is carried out by temperature treatment, and doping of the unprinted silicon wafer surfaces with dopants of the opposite polarity is induced simultaneously and/or sequentially by gas-diffusion, where the printed-on boron doping paste act as diffusion barrier against the dopants of the opposite polarity.

24. A process for the doping of silicon wafers by boron doping pastes according to claim 1, comprising
a) printing silicon wafers locally on one or both sides or over the entire surface on one side with said boron doping paste, the printed-on paste is dried, compacted, and the silicon wafers are subsequently subjected to subsequent gas-phase diffusion with, optionally, phosphoryl chloride, giving p-type dopings in the printed regions and n-type dopings in the regions subjected exclusively to gas-phase diffusion, or
b) said boron doping paste printed over a large area onto the silicon wafer is compacted, and local doping of the underlying substrate material is initiated from the dried and/or compacted paste with the aid of laser irradiation, followed by high-temperature treatment, wherein diffusion and doping are induced for the production of two-stage p-type doping levels in the silicon, or
c) the silicon wafer is printed locally on one side with said boron doping paste, where the structured deposition may optionally have alternating lines, the printed structures are dried and compacted, and the silicon wafer is subsequently coated over the entire surface on the same side of the wafer with the aid of PVD- and/or CVD-deposited phosphorus-doping dopant sources, where the printed structures of the boron doping paste are encapsulated, and the entire overlapping structure is brought to structured doping of the silicon wafer by high-temperature treatment, where the printed-on boron paste acts as diffusion barrier against the phosphorus-containing dopant source located on top and the dopant present therein, or
d) the silicon wafer is printed locally on one side with said boron doping paste, where the structured deposition may optionally have alternating lines, the printed structures are dried and compacted, and the silicon wafers are subsequently coated over the entire surface on the same side of the wafer with the aid of phosphorus-doping doping inks or doping pastes, where the printed structures of the boron doping paste are encapsulated, and the entire overlapping structure is brought to structured doping of the silicon wafer by high-temperature treatment, and where the printed-on boron paste acts as diffusion barrier against the phosphorus-containing dopant source located on top and the dopant present therein, or
e) the silicon wafer is printed locally on one side with said boron doping paste, where the structured deposition may optionally have alternating lines, the printed structures are dried and compacted, and the silicon wafer is subsequently printed on the same side of the wafer with a negative structure compared with the preceding print with the aid of a phosphorus paste, and the entire structure is brought to structured doping of the silicon wafer on one side and over the entire surface of the opposite side by high-temperature treatment in the presence of a conventional phosphorus-based gas-phase diffusion source, optionally, phosphoryl chloride, where the printed-on boron paste acts as diffusion barrier against the other phosphorus-containing diffusion sources present at the same time, or
f) the silicon wafer is printed locally on one side with said boron doping paste, where the structured deposition may optionally have alternating lines, the printed structures are dried and compacted, and the silicon wafer is subsequently printed on the same side of the wafer with a negative structure compared with the preceding print with the aid of a phosphorus paste, the opposite side of the same wafer is subsequently printed with a further phosphorus doping paste, where the sequence of the printing steps of application of the phosphorus doping pastes need not necessarily take place in the said series, and the entire structure is brought to structured doping of the silicon wafer on one side and over the entire surface of the opposite side by high-temperature treatment, where the printed-on boron paste acts as diffusion barrier against the other phosphorus-containing diffusion sources present at the same time.
